(19) United States
(12) Patent Application Publication
(10) Pub. No.: US 2025/0212472 A1
(43) Pub. Date: Jun. 26, 2025

(54) GAA NANOSHEET FET WITH SOURCE/DRAIN EXTENSION

(71) Applicant: INTERNATIONAL BUSINESS MACHINES CORPORATION, ARMONK, NY (US)

(72) Inventors: Shogo Mochizuki, Mechanicville, NY (US); Erin Stuckert, Albany, NY (US)

(21) Appl. No.: 18/393,597

(22) Filed: Dec. 21, 2023

(51) Int. Cl. H01L 29/08; H01L 29/06; H01L 29/423; H01L 29/66; H01L 29/775; H01L 29/786

(52) U.S. Cl. CPC H10D 62/151; H10D 30/014; H10D 30/43; H10D 30/6735; H10D 30/6757; H10D 62/121; H10D 64/017

(57) ABSTRACT

A semiconductor device includes a source/drain region adjacent to a gate channel, a plurality of nanosheets extended vertically at the gate channel, and a source/drain extension (SDE) between the source/drain region and the plurality of nanosheets. Portions of the SDE in vicinity of the source/drain region are doped with a first dopant.

### BACKGROUND

### Technical Field

The present disclosure generally relates to transistors, and more particularly, to transistors with source/drain extension structure and methods of creation thereof.

### Description of the Related Art

Gate-all-around (GAA) transistors provide electrostatic control of channel potential for scaled transistors with reduced short-channel effects. Typically, the gate material of a GAA fully wraps around nanowire or nanosheet semiconductor channel regions. The additional gate control reduces (e.g., minimizes) uncontrolled source/drain charge influence on the channel allowing shorter gate lengths. The source/drain extensions are lightly doped shallow regions between the transistor channel and heavier doped source/drain contact regions. The source/drain regions create a transition region between channel and contacts to enhance transistor scalability through reduced hot carrier effects for dependable low-power operation.

### SUMMARY

According to an embodiment, a semiconductor device includes a source/drain region adjacent to a gate channel, a plurality of nanosheets extended vertically at the gate channel, and a source/drain extension (SDE) between the source/drain region and the plurality of nanosheets. Portions of the SDE in vicinity of the source/drain region are doped with a first dopant.

In some embodiments, the semiconductor device is a nanosheet gate-all-around field-effect transistor (GAA FET).

In some embodiments, the plurality of nanosheets is made of silicon.

In some embodiments, the semiconductor device is a p-type field-effect transistor, and the first dopant is a p-dopant. The p-dopant can be Boron (B), Gallium (Ga), or a combination of two or more p-type dopants.

In some embodiments, the semiconductor device is an n-type field-effect transistor, and the first dopant is a n-type dopant. The n-type dopant can be Phosphorous (P), Arsenic (As), or a combination of two or more n-type dopants.

In some embodiments, the first dopant is a same material as a source/drain region dopant.

In some embodiments, the first dopant is different from a source/drain region dopant.

In some embodiments, the doped portions of SDE are doped with a drive-in anneal along a direction orthogonal to the gate channel.

In some embodiments, a thickness of the plurality of nanosheets is smaller than a thickness of the doped portions of the SDE.

In some embodiments, the semiconductor device includes a first layer encapsulating each of the plurality of nanosheets.

In some embodiments, the first layer is made of silicon or silicon germanium.

According to an embodiment, a method for forming a semiconductor device includes forming a source/drain region adjacent to a gate channel, forming a plurality of nanosheets extended vertically at the gate channel, forming a source/drain extension (SDE) between the source/drain region and the plurality of nanosheets, and doing portions of the SDE in vicinity of the source/drain region with a first dopant.

In some embodiments, the method includes doping the doped portions of SDE with a drive-in anneal along a direction orthogonal to the gate channel.

In some embodiments, the method includes trimming the plurality of nanosheets, wherein a thickness of the trimmed plurality of nanosheets is smaller than a thickness of the doped portions of the SDE.

In some embodiments, the method includes encapsulating each of the plurality of nanosheets by a first layer.

In some embodiments, the first layer is made of silicon or silicon germanium.

According to another embodiment, a semiconductor device includes a source/drain region adjacent to a gate channel, a plurality of nanosheets extended vertically at the gate channel, a spacer layer between each of the plurality of nanosheets, and a dopant layer between each of the plurality of nanosheets and the source/drain region, and between each of the plurality of nanosheets and the spacer layer.

In some embodiments, the semiconductor device is a nanosheet gate-all-around field-effect transistor (GAA FET).

In some embodiments, the plurality of nanosheets is made of silicon.

In some embodiments, the semiconductor device is a p-type field-effect transistor, and the first dopant is a p-dopant. The p-dopant can be Boron (B), Gallium (Ga), or a combination of two or more p-type dopants. In some embodiments, the semiconductor device is an n-type field-effect transistor, and the first dopant is an n-type dopant. The n-type dopant can be Phosphorous (P) or Arsenic (As), or a combination of two or more n-type dopants.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1B illustrate a semiconductor device, in accordance with some embodiments.

FIGS. 2A-2B illustrate a semiconductor device after annealing, in accordance with some embodiments.

FIGS. 3A-3B illustrate a semiconductor device after nanosheet trimming and gate channel grow back, in accordance with some embodiments.

FIGS. 4A-4B illustrate a semiconductor device after etching the gate spacer, in accordance with some embodiments.

FIGS. 5A-5B illustrate a semiconductor device after indentation of the layers of silicon germanium (SiGe), in accordance with some embodiments.

FIGS. 6A-6B illustrate a semiconductor device after the formation of source/drain extension (SDE), in accordance with some embodiments.

FIGS. 7A-7B illustrate a semiconductor device after a rapid thermal annealing, in accordance with some embodiments.

FIGS. 8A-8B illustrate a semiconductor device after the formation of the inner spacer, in accordance with some embodiments.

FIGS. 9A-9B illustrate a semiconductor device after the formation of the source/drain region, in accordance with some embodiments.

FIGS. 10A-10B illustrate a semiconductor device after removal of the dummy gate and hard mask, in accordance with some embodiments.

FIGS. 11A-11B illustrate a semiconductor device after removal of the layers of SiGe, in accordance with some embodiments.

FIGS. 12A-12B illustrate a semiconductor device after etching the layers of Si, in accordance with some embodiments.

FIGS. 13A-13B illustrate a semiconductor device after the gate channel grows back, in accordance with some embodiments.

FIGS. 14A-14B illustrate a semiconductor device after deposition of the dielectric layer, in accordance with some embodiments.

FIG. 15 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

The concepts herein relate to nanosheet field-effect transistor (FET), which are fundamental electronic devices that have revolutionized the field of electronics and how various elements of the transistors are electrically connected.

Gate-all around (GAA) transistors provide electrostatic control of channel potential for scaled transistors with reduced short-channel effects. Typically, the gate material wraps around nanowire or nanosheet semiconductor channel regions. The additional gate control minimizes uncontrolled source/drain charge influence on the channel allowing shorter gate lengths. Moreover, thin nanowire/sheet channels are more easily depleted allowing lower voltage and/or higher on-state current flow. Fabrication of GAA transistors involve advanced processes to define vertical or horizontal nano-channel structures that can be surrounded by deposited gate dielectric and metal. However, precise dimension control and isolation for the wrapped gate and contacts to nano-channel structures adds complexity.

The source/drain extensions (SDEs) have a lighter dopant concentration compared to the main source/drain regions, which creates a grading profile. The lighter doping causes a lower peak electric field at the extension edge near the gate-controlled channel. Such a lower peak electric field can improve reliability of the transistor. The SDE still allows current to flow to and from the channel but has higher resistance than the heavier doped source/drain contacts. The doping concentration transitions gradually from the channel to extension to source/drain, which avoids abrupt interfaces. SDEs further allow independent optimization to control short-channel and parasitic resistance effects, while lower electric field minimizes hot carrier injection improving transistor longevity.

In a GAA nanosheet architecture, the source and drain junctions are formed by a dopant diffusion process starting from the heavily doped source/drain (S/D) contact regions adjacent to the gate structure. Successfully activating the SDEs and achieving abrupt, ultra-shallow low-resistance source/drain contacts relies on tight control of this diffusion process. However, there are inherent nanosheet integration challenges that make attaining precise abrupt junction profiles difficult. The tall, thin stacked nanosheet channels provide a wide exposed surface area for rapid diffusion. Also, the proximity between the gate and source/drain structures is extremely small; about 10-15 nm spacer separation. Rapid transient enhanced diffusion can cause variation in junction depth profile between nanosheets across the gate pitch. Furthermore, diffusion down the nanosheet sidewalls below the gate risks creating inadvertent channel doping and high gate leakage paths if dopants diffuse laterally under the gate. These unwanted effects degrade transistor performance.

To tackle the above-mentioned and other problems, disclosed is a semiconductor device with an abrupt overlapped SDE.

The disclosed GAA nanosheet FET utilizes multiple horizontal channel nanosheets of silicon stacked atop one another. Each nanosheet has a gate dielectric layer (e.g., HfO2) fully wrapped around it, covered by the contiguous gate electrode surrounding all sides. Discrete source and drain regions are located at the ends of the nanosheets. Each source/drain includes a main heavily doped (n-type or p-type) region making contact to the metal interconnect. Adjacent to the gate is an SDE region with lighter doping concentration. This extension provides an abrupt dopant profile at the junction interface with the edge of the undoped channel under the gate dielectric spacer. Specifically, the SDE exhibits a sharp transition from low doping level immediately adjacent to the gate edge to sudden increased doping orders higher. Such an abrupt change in dopant profile allows low resistance while reducing (e.g., minimizing) short channel effects. The abrupt high-to-low doping profile at the junction is consistently maintained along the nanosheet vertical dimension from top to bottom stack despite the nested gate-around-all-channels architecture. This helps optimize electrical characteristics simultaneously for all the stacked nanosheet FET channels.

Accordingly, the teachings herein provide methods and systems of semiconductor device formation with source/drain extension. The techniques described herein may be implemented in a number of ways. Example implementations are provided below with reference to the following figures.

### Example Semiconductor Device With SDE Structure

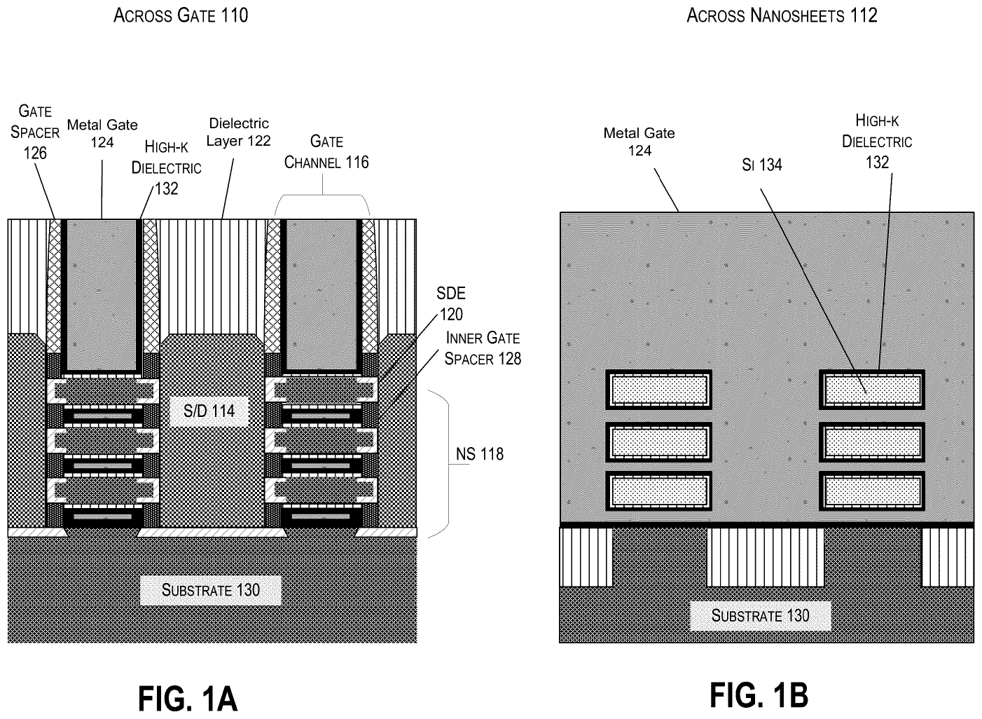

Reference now is made to FIGS. 1A-1B, which are simplified cross-section views of a semiconductor device across gates 110 and across nanosheets 112, consistent with an illustrative embodiment. The disclosed semiconductor device can include a source/drain region, S/D, 114, a gate channel 116, a plurality of nanosheets, NS, 118, a source/drain extension, SDE, 120, a dielectric layer 122, a gate metal 124, a gate spacer 126, an inner gate spacer 128, a substrate 130, and a high-k dielectric 132. The semiconductor device can be a gate-all-around nanosheet field-effect transistor (GAA nanosheet FET). Such an architecture uses vertically stacked nanoscale gate channels with a surrounding gate structure to provide improved electrostatic control for densely packed, high-performance transistor scaling necessary for future technology nodes.

Generally, the S/D 114 is a salient component that plays relevant roles in the semiconductor device's operation. In various embodiments, the S/D 114 is a region within the semiconductor material, where the current flows in and out of the semiconductor device. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region. In some embodiments, one source/drain region is located on a first transistor, and another source/drain region is located on a second transistor. In such embodiments, the first transistor can be stacked on top of the second transistor to form the semiconductor device.

Gate channel 116 is the conductive path that forms between the S/D 114 through which current flows, and is controlled by the gate electrode. The gate channel is made from silicon, or SiGe, and is situated below the gate dielectric and between the source and drain junctions. The gate channel 116 applies voltage on the gate to alter channel conductivity to turn current flow on and off by affecting carrier concentration.

In various embodiments, the gate channel 116 serves as a control element that regulates the flow of current through the semiconductor device. The gate channel 116 can be composed of a conductive material. The gate channel 116 can control the flow of electric current between the source and drain regions. In some embodiments, by applying a voltage to the gate, the channel region's conductivity is modulated, allowing the semiconductor device to either allow or block the flow of current, which in turn enables the semiconductor device to act as electronic switches or amplifiers. The gate voltage can determine whether the semiconductor device is in an “on” or “off” state. When the gate voltage is below a certain threshold, the semiconductor device is in the “off” state, and the current flow between the source and drain is effectively blocked. On the other hand, when the gate voltage exceeds the threshold, the semiconductor device enters the “on” state, allowing current to flow through the gate channel. In addition to acting as a switch, modulating the gate voltage can enable the gate channel 116 to control the current flowing through the gate channel, resulting in amplified output signals.

In an embodiment, the gate channel 116 can enable the implementation of Boolean logic operations, such as AND, OR, and NOT, by controlling the flow of current based on the input voltages. Multiple semiconductor devices can be interconnected to form complex logic circuits, enabling the execution of various computational tasks in digital systems. In some embodiments, the gate channel 116, along with other semiconductor device components, can facilitate the miniaturization and integration of electronic circuits. The ability to control the gate channel's conductivity through the gate voltage allows for compact and highly efficient circuit designs.

The NS 118 can extend vertically at the gate channel 116 and include three-dimensional structures in the gate channel 116, which are extended from a source region towards a drain region. Each nanosheet can include one or more layers.

The SDE 120 is a region of lightly doped material that extends from the source/drain region 114 to the gate channel 116. In some embodiments, the SDE 120 helps control the effective length of the gate channel 116 through which current flows in the semiconductor device. By extending into the gate channel 116, the SDE 120 effectively deceases the length of the gate channel 116. The SDE 120 provides a gradual transition between the heavily doped S/D 114 and the lightly doped gate channel 116, which can mitigate the increased leakage currents and reduced control over the gate channel 116. In some embodiments, by influencing the gate channel length, the SDE 120 allows controlling the semiconductor's threshold voltage (Vth), which in turn, enables precise switching and ensures that the semiconductor device operates in the desired mode (e.g., cutoff or saturation). In some embodiments, the SDE 120 contributes to a steeper subthreshold slope, which means the semiconductor device switches more abruptly between the off and on states, which results in improved energy efficiency and reduced power consumption in the digital circuit.

In some embodiments, portions of the SDE that are located close to the S/D 114 are doped with a dopant. Thus, the portions in the vicinity of the source/drain region 114 have a higher concentration of dopant compared to the portions of SDE in the vicinity of the nanosheets. Such a dopant concentration gradient can create a dopant profile across the direction orthogonal to the gate channel 116. In some embodiments, the doped portions of SDE are doped with the same material as the S/D 114. As a non-limiting example, the doped portions of SDE and the S/D 114 can be doped with silicon. Alternatively, the doped portions of SDE can be doped with a material that is different from the material by which the source/drain region 114 is doped. In some embodiments, the semiconductor device is a p-type FET. In such embodiments, the SDE is doped with a p-type dopant, such as Boron (B) or Gallium (Ga), or a suitable combination of two or more p-type dopants. In some embodiments, the semiconductor device is an n-type FET. In such embodiments, the SDE is doped with an n-type dopant, such as Phosphorous (P) or Arsenic (As), or any suitable combination of two or more n-type dopants.

The dielectric layer 122, e.g., interlayer dielectric, ILD, can be a low-k dielectric layer. The dielectric layer 122 is positioned between the gate metal 124 (e.g., a metal or metal alloy) and the gate channel 116. The dielectric layer 122 serves as an insulating material between the gate metal 124 and the gate channel 116. The dielectric layer 122 prevents direct electrical contact between the gate electrode and the gate channel, ensuring that the gate voltage can modulate the flow of charge carriers in the channel without unwanted leakage. In some embodiments, the dielectric layer 122 can control the flow of charge carriers (either electrons or holes) between the source and drain terminals. By applying a voltage to the gate electrode, an electric field is established across the dielectric, enabling the transistor to switch between on (conducting) and off (non-conducting) states.

The gate metal 124 can control the conductivity of the gate channel 116 beneath it. By applying a voltage to the gate electrode, an electric field is established across the dielectric layer 122. This electric field modulates the flow of charge carriers in the gate channel 116, allowing the semiconductor device to switch between different operational states (on/off or amplification).

The voltage applied to the gate metal 124, known as the gate-source voltage (Vgs), determines the threshold voltage (Vth) of the semiconductor device. The threshold voltage is the minimum Vgs to turn the semiconductor device on and allow current flow between the source and drain terminals. In some embodiments, when the gate voltage exceeds the threshold voltage, the gate metal 124 creates an electric field in the gate channel 116 that attracts or repels charge carriers. This, in turn, forms a conducting path between the source and drain terminals or isolates them when the transistor is off.

The gate spacer 126 is an insulating material layer that surrounds and isolates the gate electrode of the semiconductor device. The gate spacer 126 electrically isolates the gate channel 116 from the S/D 114 to prevent unwanted electrical leakage. In some embodiments, the gate spacer 126 can help define the length of the gate channel 116 beneath the gate electrode. In some embodiments, the gate spacer is made of silicon dioxide (SiO2), silicon nitride (Si3N4), or a low-k dielectric.

The inner gate spacer 128 is formed adjacent to the gate electrode and is made of silicon nitride, or a low-k dielectric. The inner gate spacer 128 can electrically isolate the gate channel 116 from subsequent source/drain formation steps and contacts and can reduce (e.g., minimize) parasitic capacitances between the gate channel 116 and the source/drain contacts. The high-k dielectric 132 covers sidewalls of the gate channel 116 and isolates the gate metal 124 and the gate spacer 126.

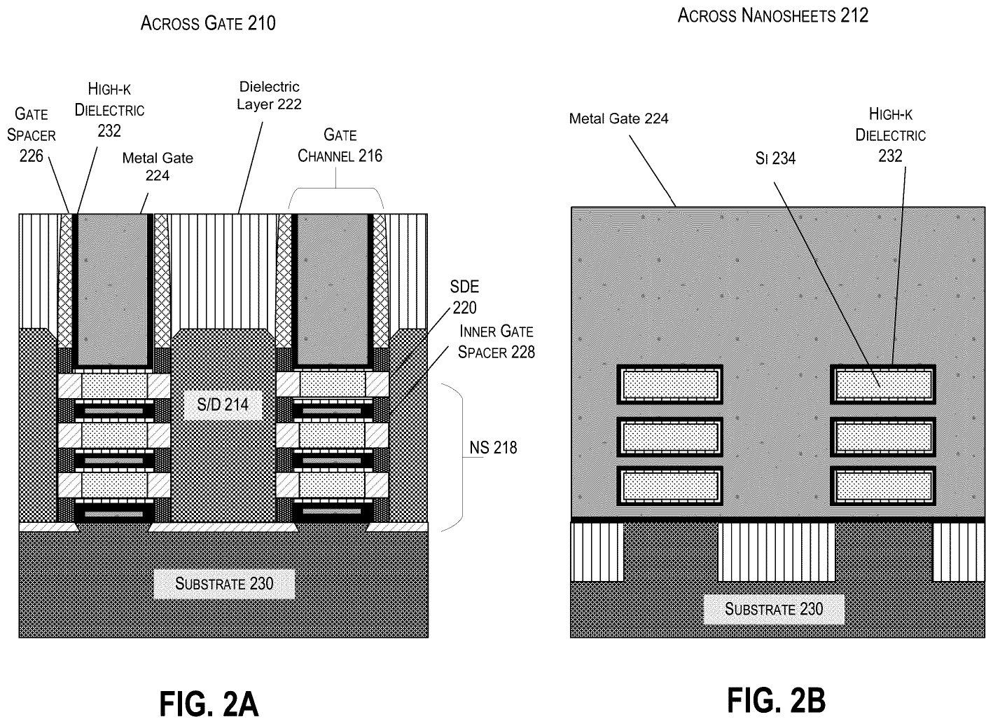

Reference now is made to FIGS. 2A-2B, which are simplified cross-section views of a semiconductor device across gates 210 and across nanosheets 212, consistent with an illustrative embodiment. The disclosed semiconductor device can include a source/drain region, S/D, 214, a gate channel 216, a plurality of nanosheets, NS, 218, a source/drain extension, SDE, 220, a dielectric layer 222, a gate metal 224, a gate spacer 226, an inner gate spacer 228, a substrate 230, and a high-k dielectric 232. The semiconductor device can be a gate-all-around nanosheet field-effect transistor (GAA nanosheet FET). Such an architecture uses vertically stacked nanoscale gate channels with a surrounding gate structure to provide improved electrostatic control for densely packed, high-performance transistor scaling necessary for future technology nodes.

Gate channel 216 is the conductive path that forms between the S/D 214 through which current flows, and is controlled by the gate electrode. The gate channel 216 can be made from silicon, or SiGe, and is situated below the gate dielectric and between the source and drain junctions. The gate channel 216 applies voltage on the gate to alter channel conductivity to turn current flow on and off by affecting carrier concentration.

In various embodiments, the gate channel 216 serves as a control element that regulates the flow of current through the semiconductor device. The gate channel 216 can be composed of a conductive material. The gate channel 216 can control the flow of electric current between the source and drain regions. In some embodiments, by applying a voltage to the gate, the channel region's conductivity is modulated, allowing the semiconductor device to either allow or block the flow of current, which in turn enables the semiconductor device to act as electronic switches or amplifiers. The gate voltage can determine whether the semiconductor device is in an “on” or “off” state. When the gate voltage is below a certain threshold, the semiconductor device is in the “off” state, and the current flow between the source and drain is effectively blocked. On the other hand, when the gate voltage exceeds the threshold, the semiconductor device enters the “on” state, allowing current to flow through the gate channel. In addition to acting as a switch, modulating the gate voltage can enable the gate channel 216 to control the current flowing through the gate channel, resulting in amplified output signals.

In an embodiment, the gate channel 216 can enable the implementation of Boolean logic operations, such as AND, OR, and NOT, by controlling the flow of current based on the input voltages. Multiple semiconductor devices can be interconnected to form complex logic circuits, enabling the execution of various computational tasks in digital systems. In some embodiments, the gate channel 216, along with other semiconductor device components, can facilitate the miniaturization and integration of electronic circuits. The ability to control the gate channel's conductivity through the gate voltage allows for compact and highly efficient circuit designs.

The NS 218 can extend vertically at the gate channel 216 and include three-dimensional structures in the gate channel 216, which are extended from a source region towards a drain region. Each nanosheet can include one or more layers.

The SDE 220 is a region of lightly doped material that extends from the S/D 214 to the gate channel 216. In some embodiments, the SDE 220 helps control the effective length of the gate channel 216 through which current flows in the semiconductor device. By extending into the gate channel 216, the SDE 220 effectively decreases the length of the gate channel 216. The SDE 220 provides a gradual transition between the heavily doped S/D 214 and the lightly doped gate channel 216, which can mitigate the increased leakage currents and reduced control over the gate channel 216. In some embodiments, by influencing the gate channel length, the SDE 220 allows controlling the semiconductor's threshold voltage (Vth), which in turn, enables precise switching and ensures that the semiconductor device operates in the desired mode (e.g., cutoff or saturation). In some embodiments, the SDE 220 contributes to a steeper subthreshold slope, which means the semiconductor device switches more abruptly between the off and on states, which results in improved energy efficiency and reduced power consumption in the digital circuit.

In some embodiments, portions of the SDE which are located close to the S/D 214 are doped with a dopant. Thus, the portions in the vicinity of the source/drain region 214 have a higher concentration of dopant compared to the portions of SDE in the vicinity of the nanosheets. Such a dopant concentration gradient can create a dopant profile across the direction orthogonal to the gate channel 216. In some embodiments, the doped portions of SDE are doped with the same material as the source/drain region 214. As a non-limiting example, the doped portions of SDE and the source/drain region 214 can be doped with silicon. Alternatively, the doped portions of SDE can be doped with a material that is different from the material by which the S/D 214 is doped. In some embodiments, the semiconductor device is a p-type FET. In such embodiments, the SDE is doped with a p-type dopant, such as Boron (B) or Gallium (Ga), or a suitable combination of two or more p-type dopants. In some embodiments, the semiconductor device is an n-type FET. In such embodiments, the SDE is doped with an n-type dopant, such as Phosphorous (P) or Arsenic (As), or any suitable combination of two or more n-type dopants.

In some embodiments, the doped portions of SDE are doped with a drive-in anneal, i.e., rapid thermal annealing, along a direction orthogonal to the gate channel 216. To that end, a high temperature cycle is used to activate implanted dopant species in the SDE by incorporating them into the crystal lattice. Electrically active dopants directly impact the SDE, and the elevated heat induces diffusion of dopants deeper into SDE structure. In such embodiments, the length of the SDE substantially increases as a result of the drive-in anneal, resulting in decreasing the length of the nanosheets. In some embodiments, the length of the drive-in annealed SDE is equal or larger than the thickness of the gate spacer 226.

The dielectric layer 222 can be a low-k dielectric layer. The dielectric layer 222 is positioned between the gate metal 224 (e.g., a metal or metal alloy) and the gate channel 216. The dielectric layer 222 serves as an insulating material between the gate metal 224 and the gate channel 216. The dielectric layer 222 prevents direct electrical contact between the gate electrode and the gate channel, ensuring that the gate voltage can modulate the flow of charge carriers in the channel without unwanted leakage. In some embodiments, the dielectric layer 222 can control the flow of charge carriers (either electrons or holes) between the source and drain terminals. By applying a voltage to the gate electrode, an electric field is established across the dielectric, enabling the transistor to switch between on (conducting) and off (non-conducting) states.

The gate metal 224 can control the conductivity of the gate channel 216 beneath it. By applying a voltage to the gate electrode, an electric field is established across the dielectric layer 222. This electric field modulates the flow of charge carriers in the gate channel 216, allowing the semiconductor device to switch between different operational states (on/off or amplification).

The voltage applied to the gate metal 224, known as the gate-source voltage (Vgs), determines the threshold voltage (Vth) of the semiconductor device. The threshold voltage is the minimum Vgs to turn the semiconductor device on and allow current flow between the source and drain terminals. In some embodiments, when the gate voltage exceeds the threshold voltage, the gate metal 224 creates an electric field in the gate channel 216 that attracts or repels charge carriers. This, in turn, forms a conducting path between the source and drain terminals or isolates them when the transistor is off.

The gate spacer 226 is an insulating material layer that surrounds and isolates the gate electrode of the semiconductor device. The gate spacer 226 electrically isolates the gate channel 216 from the S/D 214 to prevent unwanted electrical leakage. In some embodiments, the gate spacer 226 can help define the length of the gate channel 216 beneath the gate electrode. In some embodiments, the gate spacer is made of silicon dioxide (SiO2), silicon nitride (Si3N4), or a low-k dielectric.

The inner gate spacer 228 is formed adjacent to the gate electrode and is made of silicon nitride, or a low-k dielectric. The inner gate spacer 228 can electrically isolate the gate channel 216 from subsequent source/drain formation steps and contacts and can reduce (e.g., minimize) parasitic capacitances between the gate channel 216 and the source/drain contacts. The high-k dielectric 232 covers sidewalls of the gate channel 216 and isolates the gate metal 224 and the gate spacer 226.

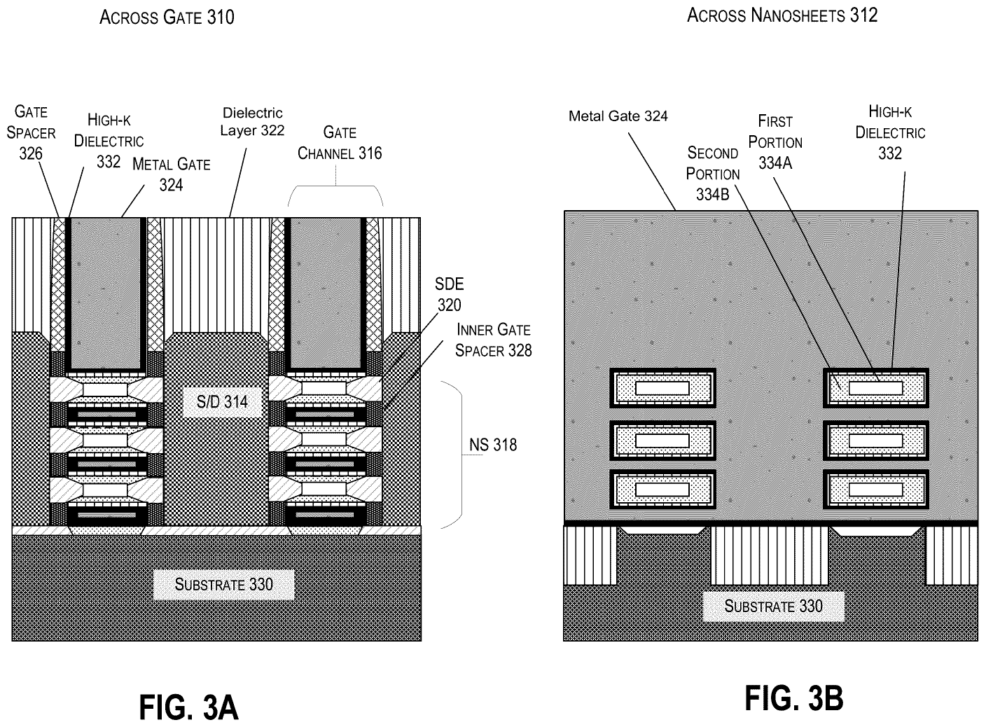

Reference now is made to FIGS. 3A-3B, which are simplified cross-section views of a semiconductor device across gates 310 and across nanosheets 312, consistent with an illustrative embodiment. The disclosed semiconductor device can include a source/drain region, S/D, 314, a gate channel 316, a plurality of nanosheets, NS, 318, a source/drain extension, SDE, 320, a dielectric layer 322, a gate metal 324, a gate spacer 326, an inner gate spacer 328, a substrate 330, and a high-k dielectric 332. The semiconductor device can be a gate-all-around nanosheet field-effect transistor (GAA nanosheet FET). Such an architecture uses vertically stacked nanoscale gate channels with a surrounding gate structure to provide improved electrostatic control for densely packed, high-performance transistor scaling necessary for future technology nodes.

Gate channel 316 is the conductive path that forms between the S/D 314 through which current flows, and is controlled by the gate electrode. The gate channel 316 can be made from silicon, or SiGe, and is situated below the gate dielectric and between the source and drain junctions. The gate channel 316 applies voltage on the gate to alter channel conductivity to turn current flow on and off by affecting carrier concentration.

In various embodiments, the gate channel 316 serves as a control element that regulates the flow of current through the semiconductor device. The gate channel 316 can be composed of a conductive material. The gate channel 316 can control the flow of electric current between the source and drain regions. In some embodiments, by applying a voltage to the gate, the channel region's conductivity is modulated, allowing the semiconductor device to either allow or block the flow of current, which in turn enables the semiconductor device to act as electronic switches or amplifiers. The gate voltage can determine whether the semiconductor device is in an “on” or “off” state. When the gate voltage is below a certain threshold, the semiconductor device is in the “off” state, and the current flow between the source and drain is effectively blocked. On the other hand, when the gate voltage exceeds the threshold, the semiconductor device enters the “on” state, allowing current to flow through the gate channel. In addition to acting as a switch, modulating the gate voltage can enable the gate channel 316 to control the current flowing through the gate channel, resulting in amplified output signals.

In an embodiment, the gate channel 316 can enable the implementation of Boolean logic operations, such as AND, OR, and NOT, by controlling the flow of current based on the input voltages. Multiple semiconductor devices can be interconnected to form complex logic circuits, enabling the execution of various computational tasks in digital systems. In some embodiments, the gate channel 316, along with other semiconductor device components, can facilitate the miniaturization and integration of electronic circuits. The ability to control the gate channel's conductivity through the gate voltage allows for compact and highly efficient circuit designs.

The NS 318 can extend vertically at the gate channel 316 and include three-dimensional structures in the gate channel 316, which are extended from a source region towards a drain region. Each nanosheet can include one or more layers. In some embodiments, each of the plurality of nanosheets includes a first portion 334A and a second portion 334B. To that end, the nanosheets shown in FIGS. 1A-1B are trimmed. That is, the top surface, the bottom surface, and side surface of the nanosheets are shrunk via a selective etching, thus the thickness of the nanosheets are decreased. Subsequently, an undoped layer of a material, i.e., Si or SiGe, is grown back on the top surface, the bottom surface, and side surface of the nanosheet. As a result, the nanosheets can include the first portion 334A in the middle of the nanosheets encapsulated by the second portion 334B. The first portion 334A is made of silicon. In some embodiments, the second portion 334B, which covers the top surface and the bottom surface of the first portion 334A, is made of un-doped silicon or un-doped SiGe.

The SDE 320 is a region of lightly doped material that extends from the S/D 314 to the gate channel 316. In some embodiments, the SDE 320 helps control the effective length of the gate channel 316 through which current flows in the semiconductor device. By extending into the gate channel 316, the SDE 320 effectively decreases the length of the gate channel 316. The SDE 320 provides a gradual transition between the heavily doped S/D 314 and the lightly doped gate channel 316, which can mitigate the increased leakage currents and reduced control over the gate channel 316. In some embodiments, by influencing the gate channel length, the SDE 320 allows controlling the semiconductor's threshold voltage (Vth), which in turn, enables precise switching and ensures that the semiconductor device operates in the desired mode (e.g., cutoff or saturation). In some embodiments, the SDE 320 contributes to a steeper subthreshold slope, which means the semiconductor device switches more abruptly between the off and on states, which results in improved energy efficiency and reduced power consumption in the digital circuit.

In some embodiments, portions of the SDE which are located close to S/D 314 are doped with a dopant. Thus, the portions in the vicinity of the S/D 314 have a higher concentration of dopant compared to the portions of SDE in the vicinity of the nanosheets. Such a dopant concentration gradient can create a dopant profile across the direction orthogonal to the gate channel 316. In some embodiments, the doped portions of SDE are doped with the same material as the S/D 314. As a non-limiting example, the doped portions of SDE and the S/D 314 can be doped with silicon. Alternatively, the doped portions of SDE can be doped with a material that is different from the material by which the S/D 314 is doped. In some embodiments, the semiconductor device is a p-type FET. In such embodiments, the SDE is doped with a p-type dopant, such as Boron (B) or Gallium (Ga), or any suitable combination of two or more p-type dopants. In some embodiments, the semiconductor device is an n-type FET. In such embodiments, the SDE is doped with an n-type dopant, such as Phosphorous (P) or Arsenic (As), or any suitable combination of two or more dopants.

In some embodiments, the doped portions of SDE are doped with a drive-in anneal along a direction orthogonal to the gate channel 316. In such embodiments, the length of the SDE substantially increases as a result of the drive-in anneal, resulting in decreasing the length of the nanosheets. In some embodiments, the length of the drive-in annealed SDE is equal or larger than the thickness of the gate spacer 326.

The dielectric layer 322 can be a low-k dielectric layer. The dielectric layer 322 is positioned between the gate metal 324 (e.g., a metal or metal alloy) and the gate channel 316. The dielectric layer 322 serves as an insulating material between the gate metal 324 and the gate channel 316. The dielectric layer 322 prevents direct electrical contact between the gate electrode and the gate channel, ensuring that the gate voltage can modulate the flow of charge carriers in the channel without unwanted leakage. In some embodiments, the dielectric layer 322 can control the flow of charge carriers (either electrons or holes) between the source and drain terminals. By applying a voltage to the gate electrode, an electric field is established across the dielectric, enabling the transistor to switch between on (conducting) and off (non-conducting) states.

The gate metal 324 can control the conductivity of the gate channel 316 beneath it. By applying a voltage to the gate electrode, an electric field is established across the dielectric layer 322. This electric field modulates the flow of charge carriers in the gate channel 316, allowing the semiconductor device to switch between different operational states (on/off or amplification).

The voltage applied to the gate metal 324, known as the gate-source voltage (Vgs), determines the threshold voltage (Vth) of the semiconductor device. The threshold voltage is the minimum Vgs to turn the semiconductor device on and allow current flow between the source and drain terminals. In some embodiments, when the gate voltage exceeds the threshold voltage, the gate metal 324 creates an electric field in the gate channel 316 that attracts or repels charge carriers. This, in turn, forms a conducting path between the source and drain terminals or isolates them when the transistor is off.

The gate spacer 326 is an insulating material layer that surrounds and isolates the gate electrode of the semiconductor device. The gate spacer 326 electrically isolates the gate channel 316 from the S/D 314 to prevent unwanted electrical leakage. In some embodiments, the gate spacer 326 can help define the length of the gate channel 316 beneath the gate electrode. In some embodiments, the gate spacer is made of silicon dioxide (SiO2), silicon nitride (Si3N4), or a low-k dielectric.

The inner gate spacer 328 is formed adjacent to the gate electrode and is made of silicon nitride, or a low-k dielectric. The inner gate spacer 328 can electrically isolate the gate channel 316 from subsequent source/drain formation steps and contacts and can reduce (e.g., minimize) parasitic capacitances between the gate channel 316 and the source/drain contacts. The high-k dielectric 332 covers sidewalls of the gate channel 316 and isolates the gate metal 324 and the gate spacer 326.

Example Processes for Semiconductor Device with SDE Structures

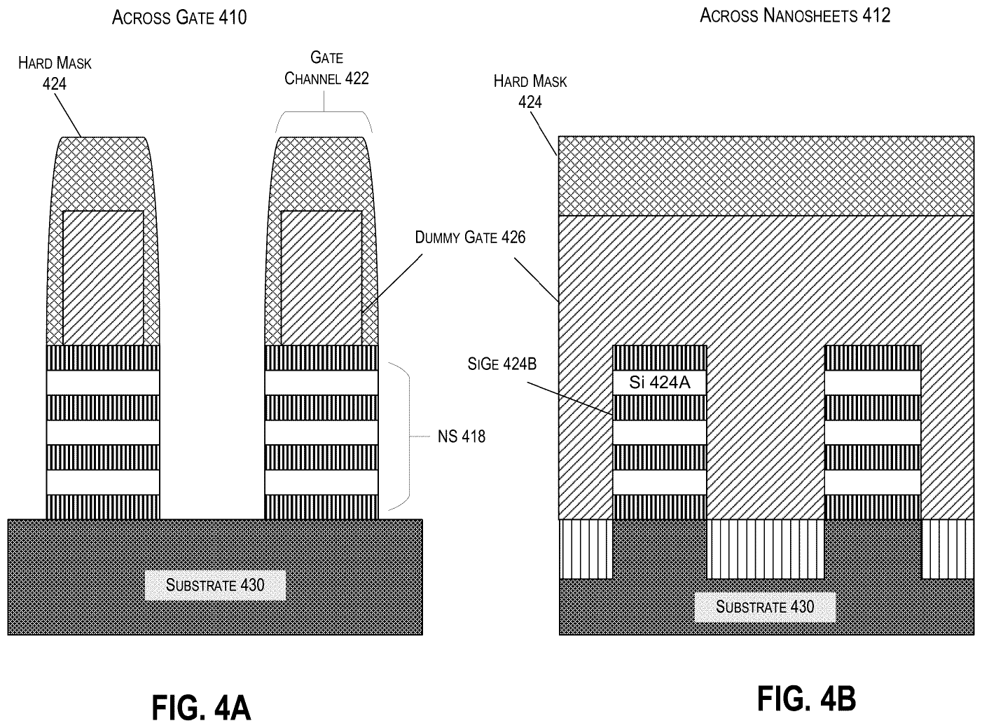

With the foregoing description of an example semiconductor device, it may be helpful to discuss an example process of manufacturing the same. To that end, FIGS. 4-14 illustrate various steps in the manufacture of a semiconductor device, consistent with illustrative embodiments. As noted above, figures denoted by A and B illustrate an act of fabrication of the semiconductor device from a different point of view.

FIGS. 4A-4B illustrate a semiconductor device after spacer formation, in accordance with some embodiments. The semiconductor device is shown across the gate 410 and across the nanosheets 412, and can include a substrate 430, a plurality of nanosheets 418 of alternating layers of Si 424A and SiGe 424B, a gate channel 422, a dummy gate 426 and a hard mask 424.

In the illustrative example depicted in FIGS. 4A-4B, the semiconductor device is depicted as being on silicon as the substrate 430, while it will be understood that other types as substrates may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate 430 may include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In some embodiments, the plurality of nanosheets 418 can be formed by alternating layers of Si 424A and SiGe 424B, in which sidewalls of the SiGe 424B layers are indented and covered by the inner spacer. The SiGe 424B layers can subsequently be removed and replaced with gate metal materials.

The dummy gate 426 is a temporary disposable gate structure used in replacement metal gate transistor fabrication, which enables proper source/drain formation aligned to a gate structure before the final metal gate is integrated. In some embodiments, the dummy gate 426 includes deposited polysilicon and oxide layers.

The hard mask 424 is a non-photosensitive protective masking material that includes durable materials such as silicon dioxide or silicon nitride. In some embodiments, the hard mask 424 is patterned using a lithographic technique by transferring the mask design into the hard mask layer before removing resist. The hard mask 424 shields the underlying layers during subsequent etching steps due to its thinner robust nature compared to resist. After the etching, the hard mask pattern transfer is complete and the hard mask may be removed, or sometimes part of the mask is retained. In some embodiments, the dummy gate 426, and the hard mask 424 are removed by a reactive ion etching (RIE) technique. Generally, RIE is a dry etching process used in semiconductor device fabrication to remove materials from the surface of a substrate selectively. In some embodiments, RIE can involve the use of reactive ions and plasma to react with and remove specific materials chemically. In an embodiment, the RIE process begins by placing the semiconductor device inside a vacuum chamber. The chamber is then evacuated to create a low-pressure environment. Reactive gases, which can include a combination of a chemically reactive gas and an inert gas, are introduced into the chamber. The chemically reactive gas, such as fluorine-based gases (e.g., CF4, SF6) or chlorine-based gases (e.g., Cl2), can react with the material to be etched, i.e., the second substrate, Si, while the inert gas, e.g., argon, can help to control the ion bombardment.

In some embodiments, radiofrequency or microwave power is applied to create a plasma within the chamber. In such embodiments, power excites the gas molecules, causing them to ionize and form a plasma of reactive ions and electrons. The plasma can include reactive ions that chemically react with the silicon. The reactive ions bombard the substrate surface, break chemical bonds and remove silicon. In various embodiments, the RIE process can be selective, meaning it can mainly affect the target material, i.e., silicon, while leaving other materials, such as masking layers or underlying layers, relatively unaffected.

In some embodiments, to achieve selective etching, an etch mask can be applied on the substrate surface prior to the RIE process. The etch mask protects certain regions from etching, allowing the reactive ions to remove the exposed material selectively. The etching process can be controlled to achieve specific etch profiles, such as vertical sidewalls or tapered structures. Parameters such as gas composition, pressure, power, and process duration are adjusted to achieve the desired etch characteristics. In some embodiments, endpoint detection techniques, such as optical emission spectroscopy or laser interferometry, can be used to determine when the etching process has reached a desired endpoint. This ensures accurate control of the etch depth and prevents over-etching. After the etching process is completed, the substrate can be cleaned to remove any residue or by-products from the etching. Cleaning can involve rinsing with solvents or plasma cleaning to ensure the substrate's surface is free from contaminants.

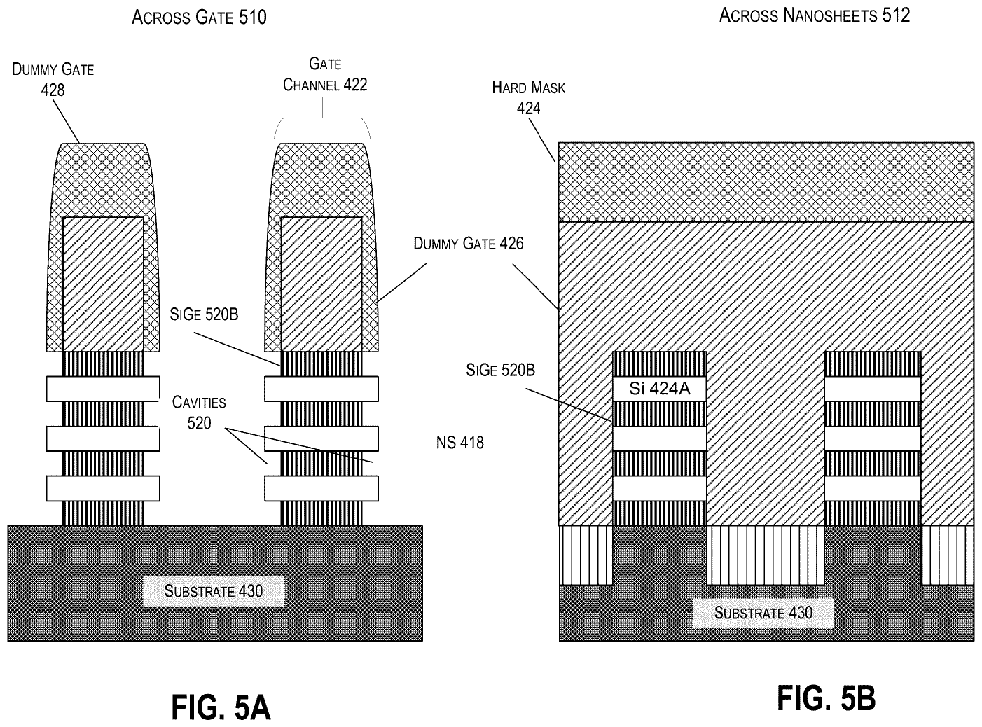

FIGS. 5A-5B illustrate a semiconductor device after SiGe indentation, in accordance with some embodiments. The semiconductor device is shown across the gate 510 and across the nanosheets 512, in which the layers of SiGe 520A in the gate channel 422 are indented and portions of the layers of SiGe 520A on both ends of the nanosheets are removed. This indentation creates a plurality of cavities 520 on both ends of the layers of SiGe 520A between each two adjacent layers of Si 520B.

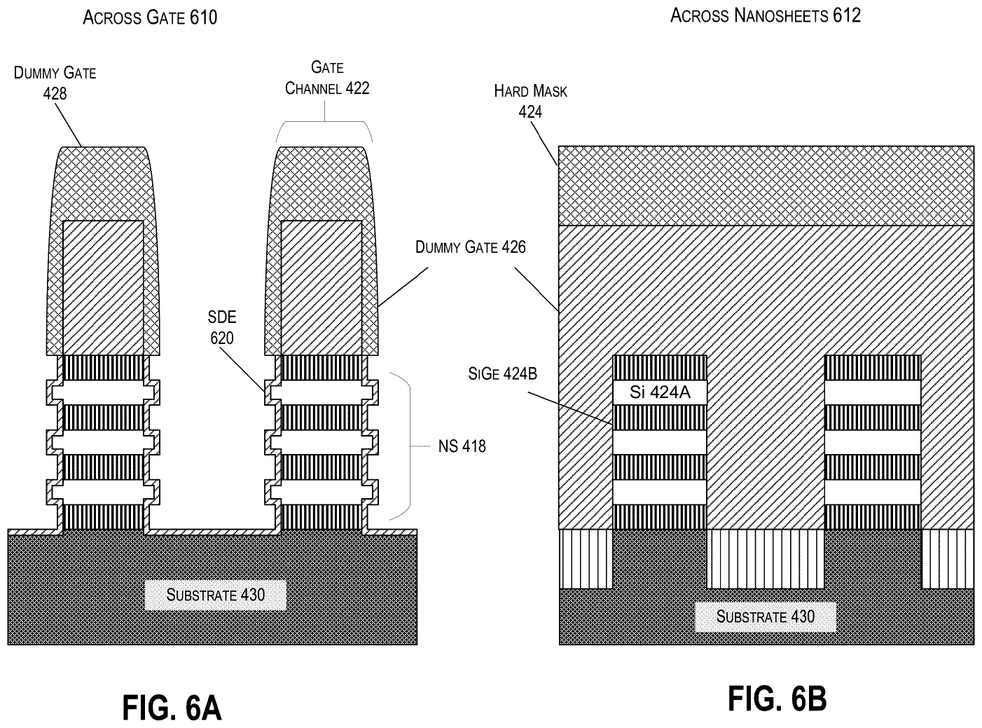

FIGS. 6A-6B illustrate a semiconductor device after the formation of the SDE, in accordance with some embodiments. The semiconductor device is shown across the gate 610 and across the nanosheets 612, in which a SDE 620 is formed via doping portions of the gate channel 422 by a dopant. The SDE 620 is formed over the sidewalls of the NS 418, including the alternating layers of Si 424A and SiGe 424B, by doping a dopant in the gate channel 422. In embodiments, where the semiconductor device is a pFET device, the dopant can be a p-type dopant, such as Boron or Gallium, or any suitable combination of two or more p-type dopants. In embodiments, where the semiconductor device is an nFET device, the dopant can be an n-type dopant, such as Phosphorus (P) or Arsenic (As), or any suitable combination of two or more n-type dopants. While in some embodiments, the SDE dopant is the same as the dopant used to dope the source/drain regions with, in some embodiments, the SDE 620 is doped with a different dopant as the dopant by which the source/drain region is doped.

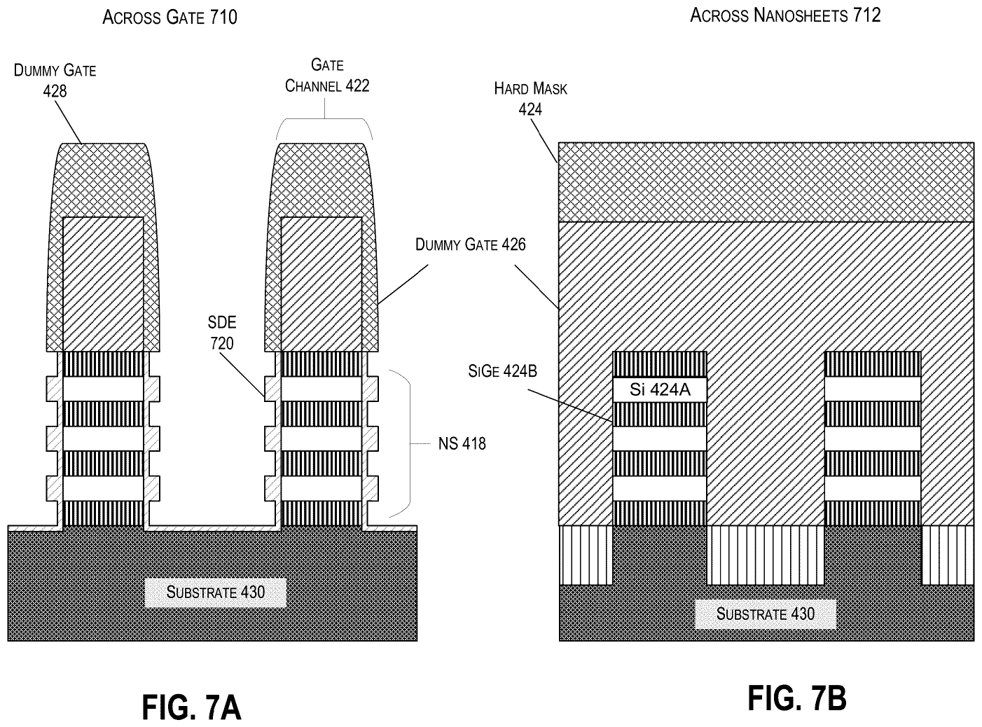

FIGS. 7A-7B illustrate a semiconductor device after a rapid thermal annealing, in accordance with some embodiments. The semiconductor device is shown across the gate 710 and across the nanosheets 712, in which a rapid thermal annealing, i.e., a drive-in annealing, is performed on the SDE 720. Rapid thermal annealing (RTA) is a specialized semiconductor manufacturing process that can rapidly heat and cool (anneal) an entire silicon wafer or other substrate in a highly controlled way, and provide faster annealing cycles lasting just seconds to minutes compared to hours needed for traditional thermal furnace annealing. In some embodiments, high intensity visible or infrared lamps, lasers, or arc-lamps are used to precisely aim at the wafer surface to create rapid heating ramp-up and cool-down rates exceeding 400° C. per second in some tool implementations. In some embodiments, temperature measurement modules such as pyrometers integrated with automated feedback control systems are utilized to ensure tight control over the full thermal profile during the pulse, which enables cresting temperatures usually between 700° C. to 1100° C. for the desired duration to activate implanted dopants, re-crystallize lattice damage, form ultra-shallow junctions, silicide contacts, perform oxidation or nitridation, and other fabrication processes needing high temperatures. The lamps allow localized targeted annealing exposure without impacting full wafer thermal budgets. In some embodiments, the annealing is performed in a controlled ambient environment enclosure with inert gas or vacuum depending on requirements.

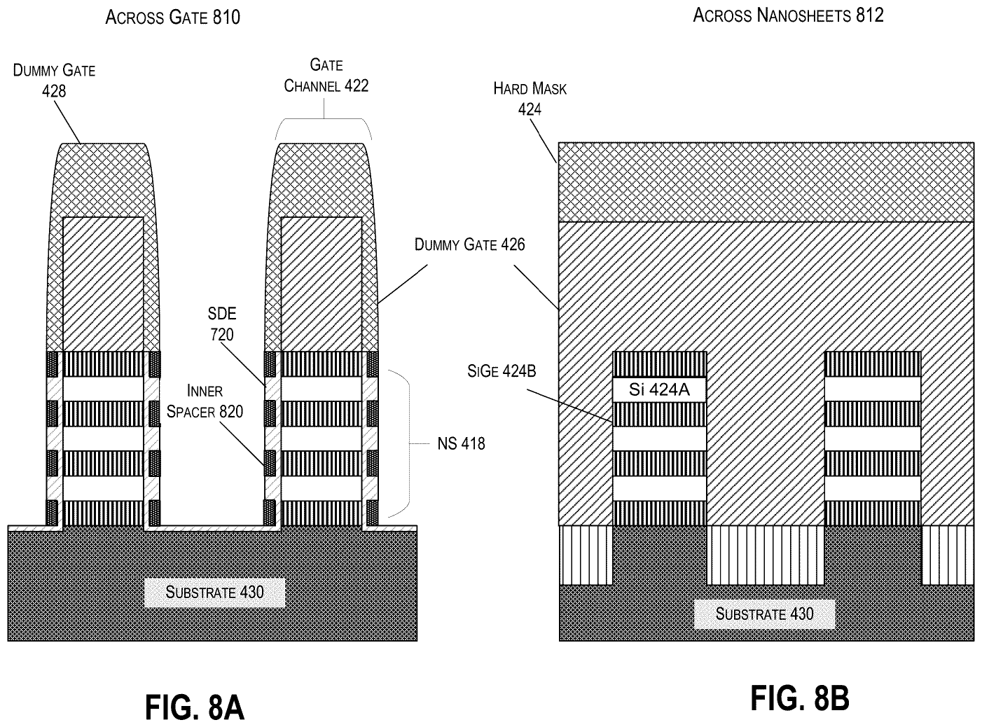

FIGS. 8A-8B illustrate a semiconductor device after the formation of the inner spacer, in accordance with some embodiments. The semiconductor device is shown across the gate channel 810 and across the nanosheets 812, in which the inner spacer 820 is formed in the gate channel 810 and within the cavities formed after indentation of the layers of SiGe. In some embodiments, the inner spacer 820 is formed by deposition of a dielectric material and etching back.

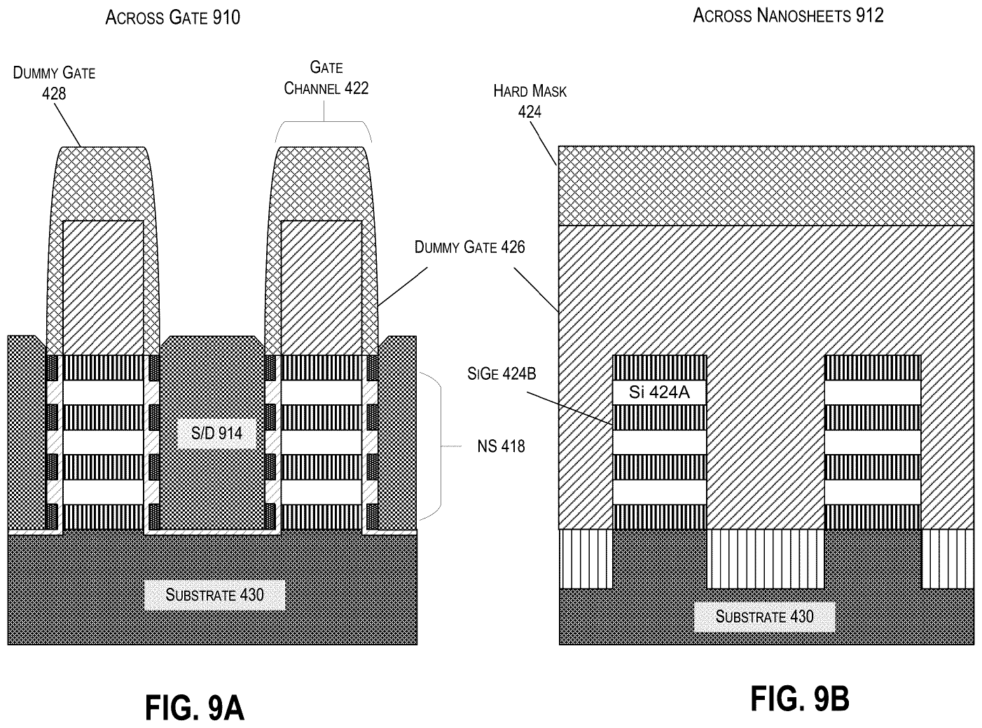

FIGS. 9A-9B illustrate a semiconductor device after the formation of the source/drain region, in accordance with some embodiments. The semiconductor device is shown across the gate 910 and across the nanosheets 912, in which the source/drain region, S/D, 914 can be epitaxially grown. The S/D 914 is in contact with the inner spacer and the SDE.

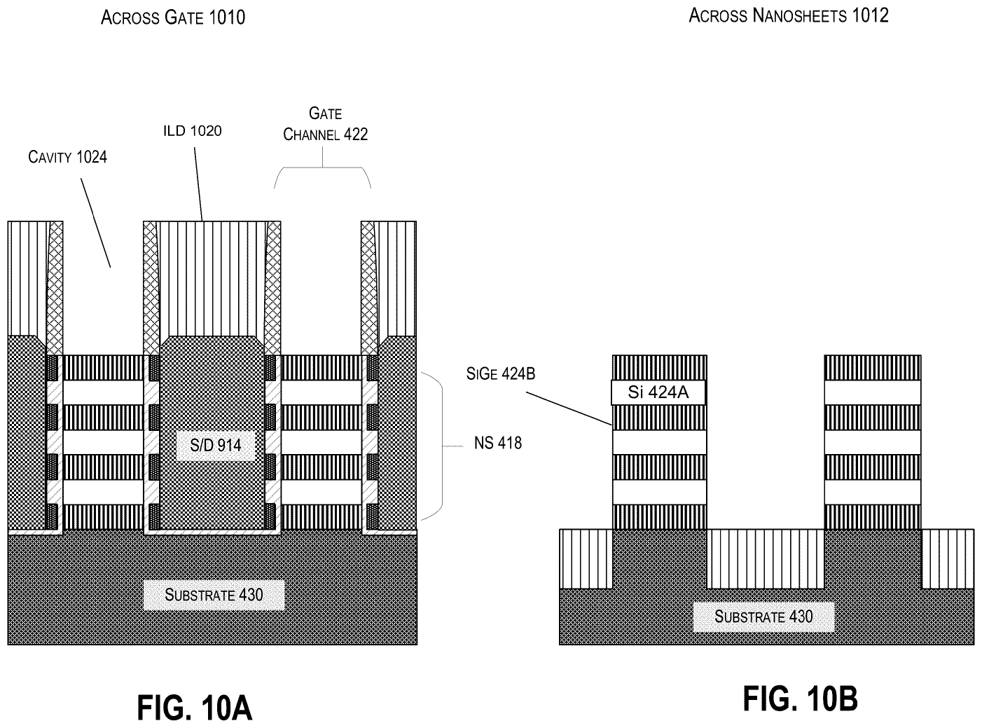

FIGS. 10A-10B illustrate a semiconductor device after the removal of the dummy gate, in accordance with some embodiments. The semiconductor device is shown across the gate 1010 and across the nanosheets 1012, in which the dummy gate and the hard mask are removed. An interlayer dielectric, ILD, 1020 is deposited over the S/D 914. As such, a cavity 1024 is formed over the NS 418. The ILD 1020 includes an electrically insulating material deposited between conductive wiring layers to isolate them vertically. In some embodiments, the ILD 1020 is made of various compositions of silicon dioxide and fluorine-doped silicon dioxide. In some embodiments, a chemical-mechanical polishing (CMP) is performed.

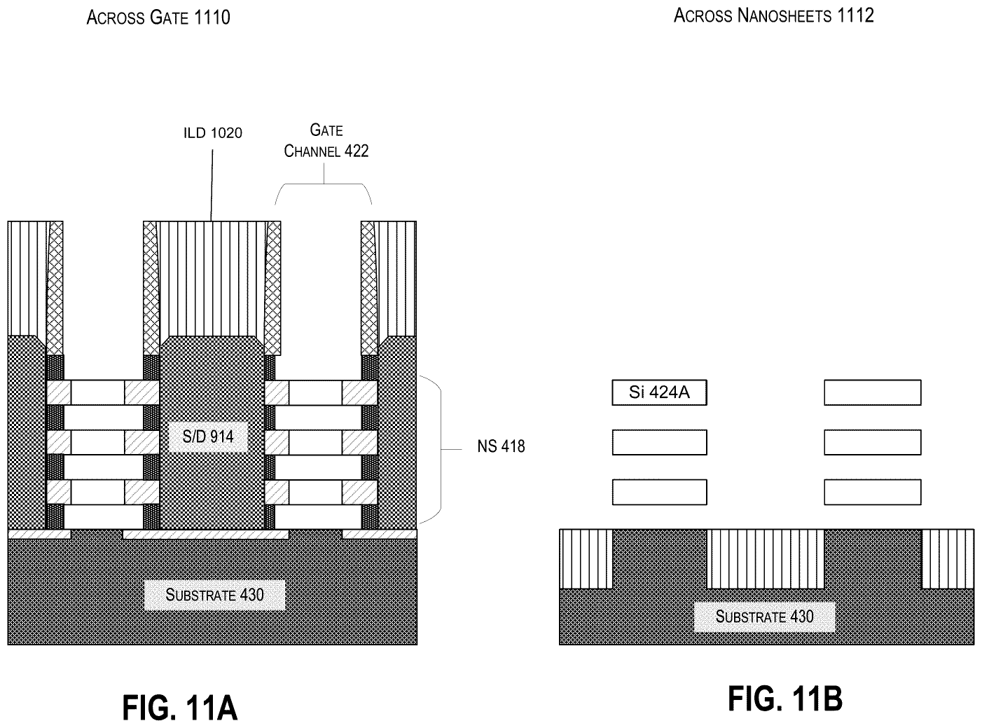

FIGS. 11A-11B illustrate a semiconductor device after the removal of the layers of SiGe, in accordance with some embodiments. The semiconductor device is shown across the gate 1110 and across the nanosheets 1112, in which the layers of SiGe in the NS 418 are selectively removed, while the layers of Si 424A remain intact.

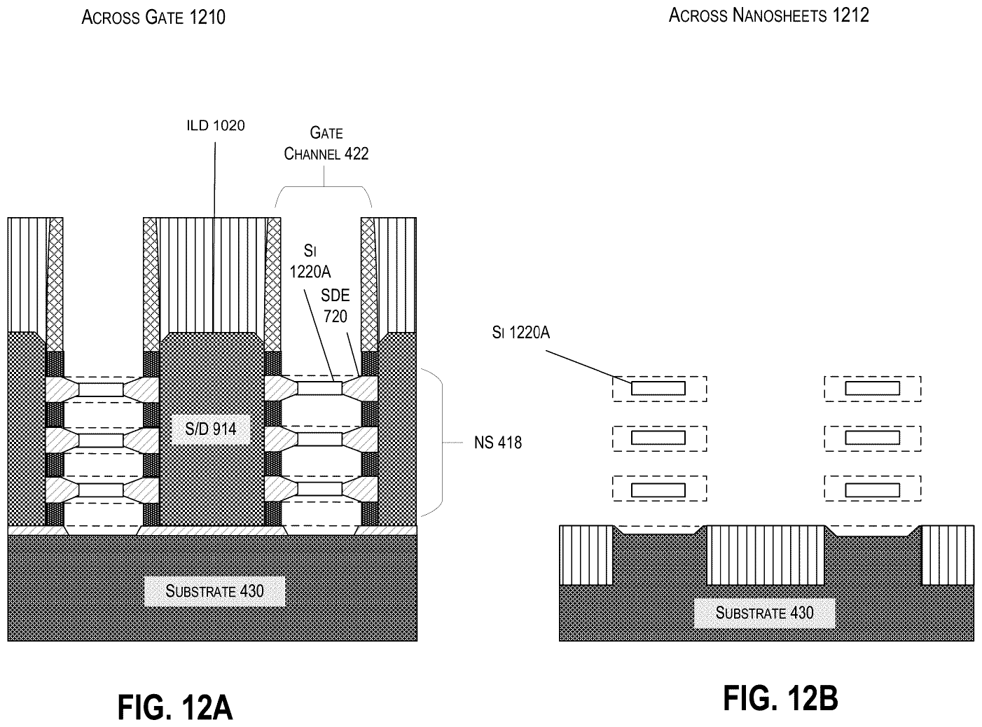

FIGS. 12A-12B illustrate a semiconductor device after the trimming of the nanosheets, in accordance with some embodiments. The semiconductor device is shown across the gate 1210 and across the nanosheets 1212, in which the layers of Si 1220A of the NS 418 are selectively etched to decrease the thickness of the layers of Si 1220A. As a result of trimming the layers of Si 1220A, the thickness of the SDE 720 becomes larger than the thickness of the trimmed layers of Si 1220A.

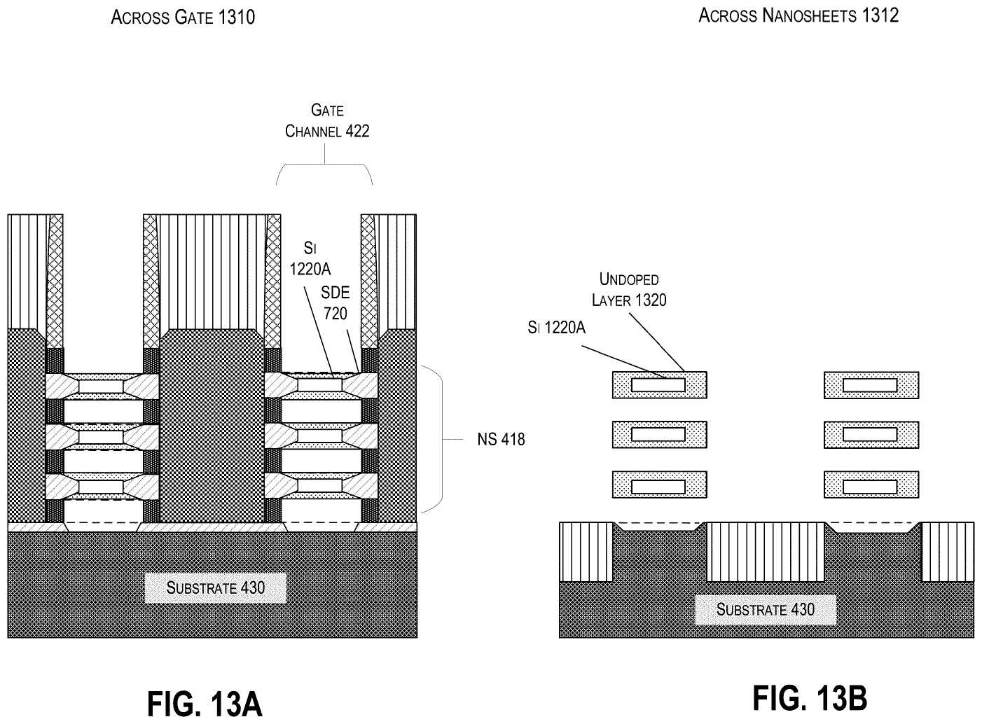

FIGS. 13A-13B illustrate a semiconductor device after the gate channel grows back, in accordance with some embodiments. The semiconductor device is shown across the gate 1310 and across the nanosheets 1312, in which an un-doped layer 1320 is formed on the top surface, the bottom surface, and the sidewall surface of the trimmed layers of Si 1220A. The un-doped layer 1320 can include silicon or silicon germanium. In some embodiments, the overall thickness of the trimmed layer of Si 1220A and the un-doped layer 1320 is substantially equal to the thickness of the SDE 720.

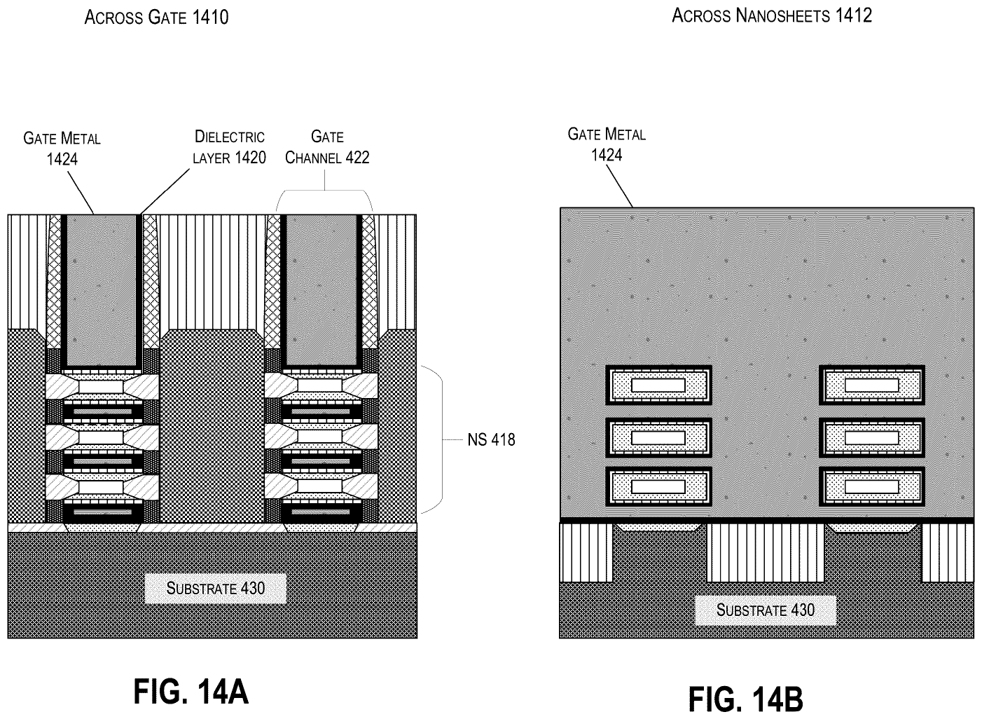

FIGS. 14A-14B illustrate a semiconductor device after the formation of dialectic layer, in accordance with some embodiments. The semiconductor device is shown across the gate 1410 and across the nanosheets 1412, in which a dialectic layer 1420 is formed over the inner sidewalls of the gate channel 422 and between and over the NS 418. Subsequently, the gate metal 1424 is deposited. The gate metal directly impacts the threshold voltage, which determines the required gate voltage to switch the transistor on and off.

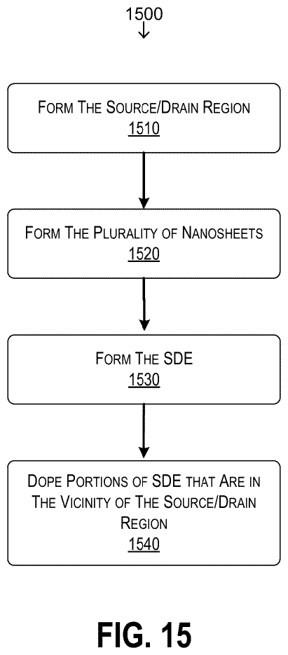

FIG. 15 illustrates a block diagram of a method 1500 for forming the semiconductor device, in accordance with some embodiments. As shown by block 1510, the source/drain region is formed. The source/drain region can be adjacent to a gate channel.

As shown by block 1520, the plurality of nanosheets is formed. The plurality of nanosheets is extended vertically at the gate channel.

As shown by block 1530, the SDE is formed. The SDE can be formed between the source/drain region and the plurality of nanosheets.

As shown by block 1540, portions of the SDE that are in vicinity of the source/drain region are doped with a dopant.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a source/drain region adjacent to a gate channel;
a plurality of nanosheets extended vertically at the gate channel; and
a source/drain extension (SDE) between the source/drain region and the plurality of nanosheets, wherein portions of the SDE in vicinity of the source/drain region are doped with a first dopant.

2. The semiconductor device of claim 1, wherein the semiconductor device is a nanosheet gate-all-around field-effect transistor (GAA FET).

3. The semiconductor device of claim 1, wherein the plurality of nanosheets is made of silicon.

4. The semiconductor device of claim 1, wherein the semiconductor device is a p-type field-effect transistor, and the first dopant is a p-type dopant, wherein the p-type dopant is Boron (B), Gallium (Ga), or a combination of two or more p-type dopants.

5. The semiconductor device of claim 1, wherein the semiconductor device is an n-type field-effect transistor, and the first dopant is an n-type dopant, wherein the n-type dopant is Phosphorous (P), Arsenic (As), or a combination of two or more n-type dopants.

6. The semiconductor device of claim 1, wherein the first dopant is a same material as a source/drain region dopant.

7. The semiconductor device of claim 1, wherein the first dopant is different from a source/drain region dopant.

8. The semiconductor device of claim 1, wherein the doped portions of the SDE are doped with a drive-in anneal along a direction orthogonal to the gate channel.

9. The semiconductor device of claim 1, wherein a thickness of the plurality of nanosheets is smaller than a thickness of the doped portions of the SDE.

10. The semiconductor device of claim 9, further comprising a first layer encapsulating each of the plurality of nanosheets.

11. The semiconductor device of claim 10, wherein the first layer is made of silicon or silicon germanium.

12. A method for forming a semiconductor device, the method comprising:
forming a source/drain region adjacent to a gate channel;
forming a plurality of nanosheets extended vertically at the gate channel;
forming a source/drain extension (SDE) between the source/drain region and the plurality of nanosheets; and
doing portions of the SDE in vicinity of the source/drain region with a first dopant.

13. The method of claim 12, further comprising: doping the doped portions of the SDE with a drive-in anneal along a direction orthogonal to the gate channel.

14. The method of claim 12, further comprising trimming the plurality of nanosheets, wherein a thickness of the trimmed plurality of nanosheets is smaller than a thickness of the doped portions of the SDE.

15. The method of claim 14, further comprising encapsulating each of the plurality of nanosheets by a first layer.

16. The method of claim 15, wherein the first layer is made of silicon or silicon germanium.

17. A semiconductor device, comprising:
a source/drain region adjacent to a gate channel;
a plurality of nanosheets extended vertically at the gate channel;
a spacer layer between each of the plurality of nanosheets; and
a dopant layer between each of the plurality of nanosheets and the source/drain region, and between each of the plurality of nanosheets and the spacer layer.

18. The semiconductor device of claim 17, wherein the semiconductor device is a nanosheet gate-all-around field-effect transistor (GAA FET).

19. The semiconductor device of claim 17, wherein the plurality of nanosheets is made of silicon.

20. The semiconductor device of claim 1,
wherein the semiconductor device is a p-type field-effect transistor, and the first dopant is a p-type dopant, wherein the p-type dopant is Boron (B), Gallium (Ga), or a combination of two or more p-type dopants, and
wherein the semiconductor device is an n-type field-effect transistor, and the first dopant is an n-type dopant, wherein the n-type dopant is Phosphorous (P), Arsenic (As), or a combination of two or more n-type dopants.
